(19) United States
(12) Patent Application Publication
(10) Pub. No.: US 2024/0400734 A1
(43) Pub. Date: Dec. 5, 2024

(54) RESIN COMPOSITION AND MANUFACTURING METHOD THEREOF

(71) Applicant: NAN YA PLASTICS CORPORATION, TAIPEI (TW)

(72) Inventors: Te-Chao Liao, TAIPEI (TW); Chi-Lin Chen, TAIPEI (TW); Hung-Yi Chang, TAIPEI (TW); Wen-Hua Lu, TAIPEI (TW); Meng-Huai Han, TAIPEI (TW)

(73) Assignee: NAN YA PLASTICS CORPORATION, TAIPEI (TW)

(21) Appl. No.: 18/357,943

(22) Filed: Jul. 24, 2023

(30) Foreign Application Priority Data
May 31, 2023 (TW) 112120284

(51) Int. Cl. C08F 212/08; C08F 212/32

(52) U.S. Cl. CPC C08F 212/08; C08F 212/32

(57) ABSTRACT

A resin composition includes a copolymer. The copolymer includes an aromatic monomer and an alicyclic monomer. A molecular weight of the copolymer is in a range of 2000 to 5000. Compared with the copolymer, a proportion of the alicyclic monomer is 1% to 30%. A manufacturing method of the resin composition is also provided.

### CROSS-REFERENCE TO RELATED APPLICATION

This application claims the priority benefit of Taiwan application serial no. 112120284, filed on May 31, 2023. The entirety of the above-mentioned patent application is hereby incorporated by reference herein and made a part of this specification.

### BACKGROUND

### Technical Field

The disclosure relates to a resin composition and a manufacturing method thereof.

### Description of Related Art

To enable a substrate to possess high-frequency transmission capabilities, it is generally required to exhibit low dielectric properties, such as a low dielectric constant (Dk) and low dielectric dissipation factor (Df). To meet these property requirements, it is common to employ a liquid rubber resin with excellent dielectric performance.

However, since liquid rubber resin is a thermosetting resin with few reactive groups, using the manufactured substrates thereof is prone to have disadvantages such as low glass transition temperature (Tg), poor reactivity, poor processability, high melt viscosity, and low peel strength. Therefore, providing a resin composition that can improve these drawbacks while maintaining good low dielectric properties for the substrate presents a significant challenge.

### SUMMARY

The disclosure provides a resin composition, in which the manufactured substrate thereof has good low dielectric properties and at the same time increases a glass transition temperature and a peel strength.

The resin composition of the disclosure includes a copolymer. The copolymer includes an aromatic monomer and an alicyclic monomer. A molecular weight of the copolymer is in a range of 2000 to 5000, and a proportion of the alicyclic monomer relative to the copolymer is 1% to 30%.

In an embodiment of the disclosure, the copolymer includes vinyl, and a proportion of the vinyl relative to the copolymer is 10% to 40%.

In an embodiment of the disclosure, the aromatic monomer includes a styrene monomer, and a proportion of the styrene monomer relative to the copolymer is 20% to 90%.

In an embodiment of the disclosure, the copolymer has a general chemical structural formula as follows:

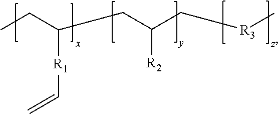

in which R₁ is

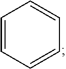

R₂ is selected from at least one of the following chemical formulas:

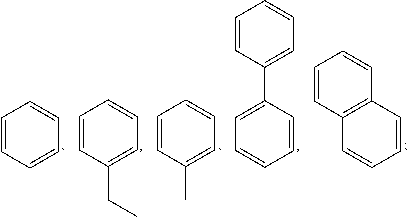

R₃ is selected from at least one of the following chemical formulas:

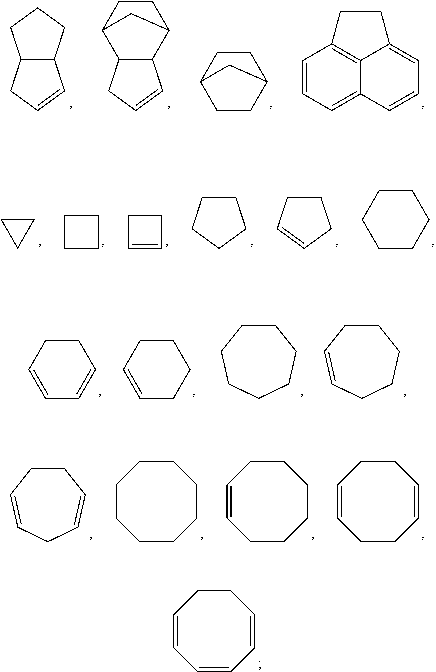

and x:y:z is 1:1 to 10:0.1 to 5.

A manufacturing method of the resin composition of the disclosure includes at least the following steps. Manufacturing the copolymer includes the following steps: dissolving at least a Lewis acid catalyst, an aromatic compound and an alicyclic compound in a solvent to form a first solution; and using an alkali solution to perform a neutralization on the first solution. The copolymer includes the aromatic monomer and the alicyclic monomer, and the molecular weight of the copolymer is in a range of 2000 to 5000. A proportion of the alicyclic monomer relative to the copolymer is 1% to 30%.

In an embodiment of the disclosure, the copolymer has the general chemical structural formula as follows:

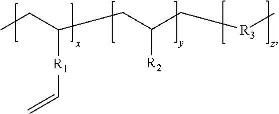

in which R₁ is derived from at least one of the following compounds: divinylbenzene, butadiene; R₂ is derived from at least one of the following compounds: styrene, 4-vinylbiphenyl, 2-vinylnaphthalene; R₃ is derived from at least one of the following compounds: acenaphthylene, cyclopentadiene, cyclobutadiene, norbornene, dicyclopentadiene; and x:y:z is 1:1 to 10:0.1 to 5.

In an embodiment of the disclosure, the Lewis acid catalyst includes SnCl₄·H₂O or BF₃·Oet₃.

In an embodiment of the disclosure, the solvent includes toluene or dimethyl formamide.

In an embodiment of the disclosure, the alkali solution includes NaHCO₃ aqueous solution.

In an embodiment of the disclosure, a reaction temperature of the neutralization is greater than or equal to 70° C.

Based on the above, the resin composition of the disclosure introduces the copolymer including the aromatic monomer and the alicyclic monomer, and as designed according to the proportion of the alicyclic monomer, the copolymer includes the non-polar backbone structure. Therefore, the manufactured substrate (such as a circuit board or a copper foil substrate) thereof has good low dielectric properties and at the same time increases the glass transition temperature and the peel strength.

To make the aforementioned features and advantageous of the disclosure more comprehensible, several embodiments is described in detail as follows.

### DESCRIPTION OF THE EMBODIMENTS

In the following detailed description, for purposes of explanation and not limitation, exemplary embodiments disclosing specific details are set forth to provide a thorough understanding of various principles of the disclosure. However, it should be apparent to people with ordinary skills in the art that the disclosure may be practiced in other embodiments that depart from the specific details disclosed herein. Furthermore, descriptions of well-known devices, methods, and materials may be omitted so as not to obscure the description of various principles of the disclosure.

In the present specification, a range represented by “a numerical value to another numerical value” is a schematic representation for avoiding listing all of the numerical values in the range in the specification. Therefore, the recitation of a specific numerical range covers any numerical value in the numerical range and a smaller numerical range defined by any numerical value in the numerical range, as is the case with the any numerical value and the smaller numerical range stated explicitly in the specification.

Unless otherwise stated, the term “between” used in the specification to define a value range is intended to cover a range equal to and between the stated endpoint values. For example, a size range between a first value and a second value means that the size range may cover the first value, the second value, and any value between the first value and the second value.

In this disclosure, non-limiting terms (for example, may, can, for example, or other similar terms) mean unnecessary or optional implementations, inclusions, additions, or existence.

Unless otherwise defined, all terms (including technical and scientific terms) used herein have the same meanings as commonly understood by people with ordinary skills in the art. Further, it should be understood that technical terms (such as those defined in commonly used dictionaries) should be interpreted consistently in the related technical context and should not be interpreted in an idealized or an overly formal sense, unless the terms are clearly defined as such.

In this embodiment, a resin composition includes a copolymer of an aromatic monomer and an alicyclic monomer. A molecular weight of the copolymer is in a range of 2000 to 5000. A proportion of the alicyclic monomer relative to the copolymer is 1% to 30%. In this way, the resin composition of this disclosure introduces the copolymer including the aromatic monomer and the alicyclic monomer, and as designed according to the proportion of the alicyclic monomer, the copolymer includes a non-polar backbone structure. Therefore, a manufactured substrate (such as a circuit board or a copper foil substrate) thereof has multiple good low dielectric properties and at the same time increases a glass transition temperature and a peel strength. Here, the molecular weight is a number average molecular weight, for example.

Furthermore, since the non-polar backbone structure is not easily polarized, a dielectric constant (Dk, 10 kz) and a dielectric dissipation factor (Df, 10 kz) of the manufactured copper foil substrate thereof is smaller than 3.1 and 0.0014. Therefore, the dielectric properties are significantly reduced and the glass transition temperature is higher than 220° C., thereby having the excellent glass transition temperature. In addition, since the copolymer has reactive double bonds, through intermolecular crosslinking, properties such as reactivity, heat resistance, chemical resistance, cold resistance, low temperature flexibility (in which brittleness is improved and flexibility is enhanced) are improved and/or solvent solubility (for example, the solubility of acetone is 40%) is increased, but the disclosure is not limited thereto.

In some embodiments, the copolymer includes vinyl. A proportion of the vinyl relative to the copolymer is 10% to 40%. For example, the aromatic monomer includes a styrene monomer. A proportion of the styrene monomer relative to the copolymer is 20% to 90%, but the disclosure is not limited thereto.

In some embodiments, the copolymer has a general chemical structural formula as follows:

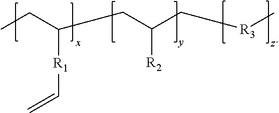

Furthermore, R₁ is

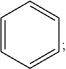

R₂ is selected from one of the following chemical formulas:

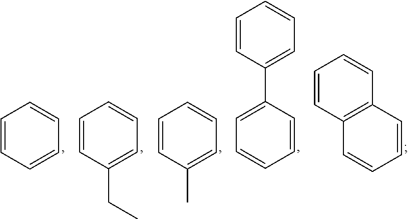

R₃ is selected from one of the following chemical formulas:

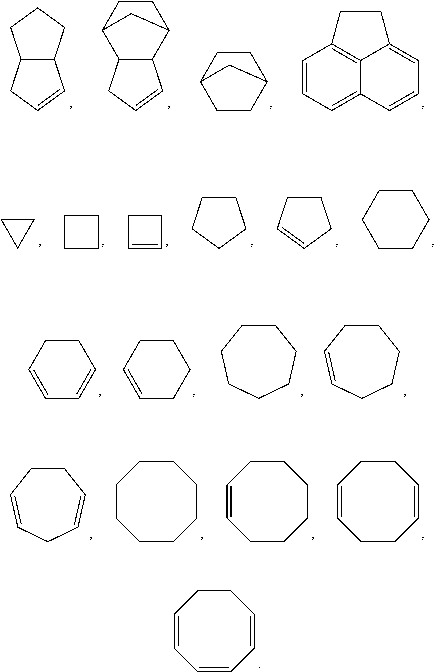

Here, a specific implementation of the copolymer may be formed by one of the combinations above but not limited to the combinations. The copolymer falls within the protection scope of the disclosure as long as the copolymer has the non-polar backbone structure.

In addition, x:y:z (a molar ratio) is 1:1 to 10:0.1 to 5. For example, x:y:z is 1:1:0.1, x:y:z is 1:10:0.1, x:y:z is 1:1:5, x:y:z is 1:5:1 or other preferable proportion in the section.

In some embodiments, R₁ is derived from one of multiple compounds as follows: divinylbenzene (DVB), butadiene; R₂ is derived from one of the compounds as follow: styrene, 4-vinylbiphenyl, 2-vinylnaphthalene; R₃ is derived from one of the compounds as follows: acenaphthylene, cyclopentadiene, cyclobutadiene, norbornene, dicyclopentadiene (DCPD). Moreover, multiple materials above are dissolved with Lewis acid catalyst in the solvent, and perform a reaction for 6 to 8 hours under an atmosphere of 0° C. to 100° C., then formed as the copolymer through a neutralization of alkali solution. The detailed manufacturing process is further described as follows. The Lewis acid catalyst is SnCl₄·5H₂O or BF₃·Oet₃, for example. The solvent is toluene or dimethyl formamide (DMF), for example. The alkali aqueous solution is NaHCO₃ aqueous solution, for example. However, the disclosure is not limited thereto. In other embodiment, the Lewis acid catalyst is a metal fluoride (for example, SnF₄, WF₆, HfF₄, ZrF₄) or a complex (for example, WCl₆, AlCl₃, SbCl₃, FeBr₃, FeCl₃, TiCl₄, ZnCl₂, NbCl₅, CF₃SO₃H, TiCl₃—Al(C₂H₅)₃, TiCl₄/LiAlH₄, TiCl₄/MAO, ZrCl₄/MAO, TiCl₃/MAO, VCl₄/MAO, CrCl₃/MAO, TiCl₄/MgCl₂, TiCl₄/NdCl₃, TiCl₄/VCl₃, TiCl₄/EtAlCl₂, RuCl₂ (=CHPh)(PCy₃)₂, RuCl₂(═CHPh)(PCy₃) (L), RuCl₂(═CHCH═CH₂)(PCy₃) (L)), for example.

It should be noted that the resin including the above copolymer is a modified liquid rubber resin, which is the resin composition formed with a polyphenylene ether resin (such as SA9000 or OPE-2st), a crosslinking agent (such as TAIC), a maleimide resin (such as MIR-3000), a flame retardant (such as PQ60) and/or a filler (such as SiO₂), for example. Moreover, a proportion of the aromatic, a proportion of the alicyclic, and a proportion of the styrene monomer may be molar ratio, but the disclosure is not limited thereto.

The following examples and comparative examples are given to illustrate the effects of the disclosure, but the scope of claims of the disclosure is not limited to the scope of the examples.

The copper foil substrates produced in the respective examples and the comparative examples were evaluated according to the following method.

The glass transition temperature (Tg): measured with a dynamic mechanical analyzer (DMA).

The dielectric constant (10 GHz): The dielectric constant at a frequency of 10 GHz was measured by a dielectric analyzer.

A dielectric loss (10 GHz): The dielectric loss at a frequency of 10 GHz was measured by the dielectric analyzer.

The peel strength: The peel strength of a metal substrate was tested according to a testing method of IPC-TM-650-2.4.8.

The heat resistance: The metal substrate was heated in a pressure cooker with a temperature of 120° C. and a pressure of 2 atm for 120 minutes, and then immersed in a soldering furnace at 288° C., and time required for an explosion was recorded. When the explosion time exceeds 10 minutes, it is indicated as “OK”. When the explosion time is shorter than 10 minutes, it is indicated as “NG”.

### <Copolymer 1 to Copolymer 6>

According to the proportion of the materials R₁, R₂ and R₃ shown in Table 1 (alkenyl group compound, aromatic compound and alicyclic compound, corresponding to the above general chemical structural formulas), the materials R₁, R₂ and R₃ were dissolved in a 24 ml solvent indicated in Table 1 with 0.2 g of the Lewis acid catalyst indicated in Table 1 to form a first solution. Moreover, multiple relevant reacting conditions were shown in Table 1. The first solution may be obtained by using a round-bottomed reaction flask equipped with a stirring mixer and introducing nitrogen into the reaction flask to remove air and moisture. The first solution was mixed evenly at 300 rpm. Then, the alkali aqueous solution (NaHCO₃ aqueous solution with a concentration of 8%) was used to perform a neutralization on the first solution. When a reaction temperature of the first solution was greater than or equal to 70° C., and a solid of the first solution was dissolved into clear liquid, the reaction was continued at the same temperature for 2 hours, so that the clear solution became a viscous solution and then subjected to the neutralization. Thereafter, the solution was filtered and vacuum-dried to obtain a copolymer 1 to a copolymer 6.

TABLE 1

| | Copolymer 1 | | Copolymer 2 | | Copolymer 3 | | Copolymer 4 | | Copolymer 5 | | Copolymer 6 | |
|---|---|---|---|---|---|---|---|---|---|---|---|---|
| R₁ | DVB | | DVB | | butadiene | | DVB | | DVB | | butadiene | |
| R₂ | styrene | | styrene | | 4-vinylbiphenyl | | 2-vinylnaphthalene | | 4-vinylbiphenyl | | 2-vinylnaphthalene | |
| R₃ | acenaphthylene | | acenaphthylene | | cyclopentadiene | | cyclopentadiene | | norbornene | | DCPD | |
| Mols Used | 0.02 | mol | 0.03 | mol | 0.01 | mol | 0.015 | mol | 0.02 | mol | 0.04 | mol |
| Corresponding to | | | | | | | | | | | | |
| Material R₁ | | | | | | | | | | | | |
| Mols Used | 0.1 | mol | 0.1 | mol | 0.1 | mol | 0.1 | mol | 0.1 | mol | 0.1 | mol |
| Corresponding to | | | | | | | | | | | | |
| Material R₂ | | | | | | | | | | | | |
| Mols Used | 0.003 | mol | 0.015 | mol | 0.004 | mol | 0.025 | mol | 0.015 | mol | 0.03 | mol |
| Corresponding to | | | | | | | | | | | | |
| Material R₃ | | | | | | | | | | | | |
| Solvent | toluene | | toluene | | toluene | | DMF | | DMF | | DMF | |
| Catalyst | SnCl₄•₅H₂O | | SnCl₄•₅H₂O | | SnCl₄•₅H₂O | | BF₃•Oet₃ | | BF₃•Oet₃ | | SnCl₄•₅H₂O | |
| Pressure | atmospheric | | atmospheric | | atmospheric | | atmospheric | | atmospheric | | atmospheric | |
| | pressure | | pressure | | pressure | | pressure | | pressure | | pressure | |
| Temperature | 70° | C. | 70° | C. | 80° | C. | 70° | C. | 90° | C. | 85° | C. |
| Time | 8 | h | 9 | h | 10 | h | 8.5 | h | 7 | h | 8 | h |

### Examples 1 to 6, Comparative Examples 1 to 6

According to the proportions of each constituent shown in Table 2, toluene was used for mixing to form a varnish of a thermosetting resin composition. The varnish was impregnated with NAN YA fiberglass cloth (manufactured by NAN YA PLASTICS CORPORATION, cloth model No.: 1078) at room temperature. Then, after drying at 130° C. (impregnator) for several minutes, a prepreg with a resin content of 60 wt % was obtained. Finally, 4 pieces of prepreg were stacked layer by layer between two pieces of 35 μm-thick copper foil at the pressure of 25 kg/cm² and the temperature of 85° C., and the temperature was kept the same for 20 minutes; then heated at a heating rate of 3° C./min until the temperature raised to 210° C., and the temperature was kept the same for 120 minutes. Next, after the temperature was cooled slowly to 130° C., a 0.5 mm-thick copper foil substrate in the Example 1 to Example 6 and Comparative Example 1 to Comparative Example 6 was obtained, in which B-1000, B-2000 (NIPPON SODA) and RI 257 (CRAY VALLEY) were a non-modified commercially available liquid rubber resin.

The relevant properties of the manufactured copper foil substrate were tested, and the results are shown in Table 2. After comparing the results of Examples 1 to 6 and Comparative Examples 1 to 6 in Table 2, the following conclusion may be drawn: compared with Comparative Examples 1 to 6, the copper foil substrate in Examples 1 to 6 has significantly increased glass transition temperature and peel strength while other properties (such as dielectric properties and heat resistance) are similar.

TABLE 2

| | | | | | | | | | | | | | | Comparative | |
|---|---|---|---|---|---|---|---|---|---|---|---|---|---|---|---|
| | | Example 1 | | Example 2 | | Example 3 | | Example 4 | | Example 5 | | Example 6 | | Example 1 | |
| Liquid | Copolymer 1 | 11.2 | wt % | — | | — | | — | | — | | — | | — | |
| Rubber | Copolymer 2 | — | | 11.2 | wt % | — | | — | | — | | — | | — | |
| Resin | Copolymer 3 | — | | — | | 11.2 | wt % | — | | — | | — | | — | |
| | Copolymer 4 | — | | — | | — | | 11.2 | wt % | — | | — | | — | |
| | Copolymer 5 | — | | — | | — | | — | | 11.2 | wt % | — | | — | |
| | Copolymer 6 | — | | — | | — | | — | | — | | 11.2 | wt % | — | |
| | B1000 | — | | — | | — | | — | | — | | — | | 11.2 | wt % |
| | B2000 | — | | — | | — | | — | | — | | — | | — | |
| | RI 257 | — | | — | | — | | — | | — | | — | | — | |
| Other | SA9000 | 19 | wt % | 19 | wt % | 19 | wt % | 19 | wt % | — | | — | | 19 | wt % |
| Constituents | OPE-2st | — | | — | | — | | — | | 19 | wt % | 19 | wt % | — | |
| | TAIC | 8.6 | wt % | 8.6 | wt % | 8.6 | wt % | 8.6 | wt % | 8.6 | wt % | 8.6 | wt % | 8.6 | wt % |
| | MIR-3000 | 4.2 | wt % | 4.2 | wt % | 4.2 | wt % | 4.2 | wt % | 4.2 | wt % | 4.2 | wt % | 4.2 | wt % |
| | PQ60 | 17 | wt % | 17 | wt % | 17 | wt % | 17 | wt % | 17 | wt % | 17 | wt % | 17 | wt % |
| | SiO₂ | 40 | wt % | 40 | wt % | 40 | wt % | 40 | wt % | 40 | wt % | 40 | wt % | 40 | wt % |

| Glass Transition | 235° | C. | 232° | C. | 230° | C. | 230° | C. | 225° | C. | 221° | C. | 192° | C. |
|---|---|---|---|---|---|---|---|---|---|---|---|---|---|---|
| Temperature | | | | | | | | | | | | | | |
| Dielectric | 3.01 | | 3.02 | | 3 | | 3.05 | | 3.02 | | 3.08 | | 3.12 | |
| Constant | | | | | | | | | | | | | | |
| Dielectric Dissipation | 1.4 | | 1.3 | | 1.3 | | 1.4 | | 1.4 | | 1.4 | | 2.3 | |
| Factor × 10³ | | | | | | | | | | | | | | |
| Peel Strength | 4.3 | lb/in | 4.1 | lb/in | 4.2 | lb/in | 4 | lb/in | 4.4 | lb/in | 4.5 | lb/in | 4.0 | lb/in |

| | | | | | | | |
|---|---|---|---|---|---|---|---|
| Heat Resistance | pass | pass | pass | pass | pass | pass | pass |

| | | Comparative | Comparative | Comparative | Comparative | Comparative |
|---|---|---|---|---|---|---|
| | | Example 2 | Example 3 | Example 4 | Example 5 | Example 6 |
| Liquid | Copolymer 1 | — | — | — | — | — |
| Rubber | Copolymer 2 | — | — | — | — | — |
| Resin | Copolymer 3 | — | — | — | — | — |
| | Copolymer 4 | — | — | — | — | — |
| | Copolymer 5 | — | — | — | — | — |
| | Copolymer 6 | — | — | — | — | — |

| | | | | | | |
|---|---|---|---|---|---|---|
| B1000 | — | — | 11.2 | wt % | — | — |

| | | | | | | | |
|---|---|---|---|---|---|---|---|
| B2000 | 11.2 | wt % | — | — | 11.2 | wt % | — |

| | | | | | | | |
|---|---|---|---|---|---|---|---|
| RI 257 | — | 11.2 | wt % | — | — | 11.2 | wt % |

| | | | | | | | | |
|---|---|---|---|---|---|---|---|---|
| Other | SA9000 | 19 | wt % | 19 | wt % | — | — | — |

| | | | | | | | | | |
|---|---|---|---|---|---|---|---|---|---|
| Constituents | OPE-2st | — | — | 19 | wt % | 19 | wt % | 19 | wt % |

| | | | | | | | | | | |
|---|---|---|---|---|---|---|---|---|---|---|
| TAIC | 8.6 | wt % | 8.6 | wt % | 8.6 | wt % | 8.6 | wt % | 8.6 | wt % |
| MIR-3000 | 4.2 | wt % | 4.2 | wt % | 4.2 | wt % | 4.2 | wt % | 4.2 | wt % |
| PQ60 | 17 | wt % | 17 | wt % | 17 | wt % | 17 | wt % | 17 | wt % |
| SiO₂ | 40 | wt % | 40 | wt % | 40 | wt % | 40 | wt % | 40 | wt % |

| Glass Transition | 182° | C. | 185° | C. | 160° | C. | 165° | C. | 178° | C. |
|---|---|---|---|---|---|---|---|---|---|---|
| Temperature | | | | | | | | | | |
| Dielectric | 3.1 | | 3.1 | | 3.06 | | 3.2 | | 3.04 | |
| Constant | | | | | | | | | | |
| Dielectric Dissipation | 2.6 | | 2.5 | | 2.4 | | 2.1 | | 2.2 | |
| Factor × 10³ | | | | | | | | | | |
| Peel Strength | 3.7 | lb/in | 3.8 | lb/in | 3.7 | lb/in | 3.2 | lb/in | 3 | lb/in |

| | | | | | |
|---|---|---|---|---|---|
| Heat Resistance | pass | pass | pass | pass | pass |

In summary of the above, the resin composition of the disclosure introduces the copolymer including the aromatic monomer and the alicyclic monomer, and as designed according to the proportion of the alicyclic monomer, so that the copolymer includes the non-polar backbone structure. Therefore, the manufactured substrate (such as the circuit board or the copper foil substrate) thereof has good low dielectric properties with improved glass transition temperature and the peel strength at the same time.

Although the disclosure has been disclosed in the above embodiments, the embodiments are not intended to limit the disclosure. Persons skilled in the art may make some changes and modifications without departing from the spirit and scope of the disclosure. The protection scope of the disclosure shall be defined by the appended claims.

What is claimed is:

1. A resin composition, comprising:
a copolymer, comprising an aromatic monomer and an alicyclic monomer, wherein a molecular weight of the copolymer is in a range of 2000 to 5000, and a proportion of the alicyclic monomer relative to the copolymer is 1% to 30%.

2. The resin composition according to claim 1, wherein the copolymer comprises vinyl, and a proportion of the vinyl relative to the copolymer is 10% to 40%.

3. The resin composition according to claim 1, wherein the aromatic monomer comprises a styrene monomer, and a proportion of the styrene monomer relative to the copolymer is 20% to 90%.

4. The resin composition according to claim 1, wherein the copolymer has a general chemical structural formula as follows: 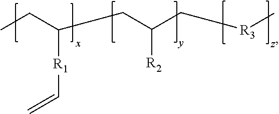
wherein
the R₁ is 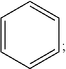
the R₂ is selected from at least one of the following chemical formulas: 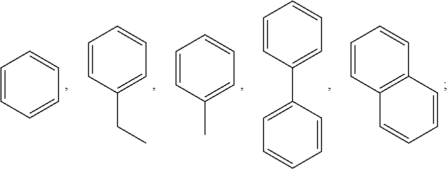
the R₃ is selected from at least one of the following chemical formulas: 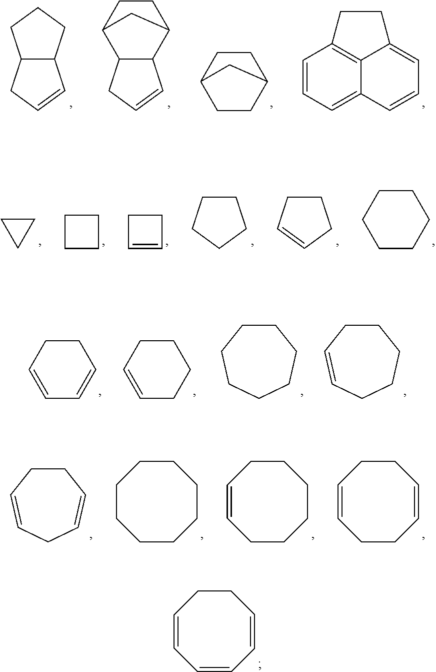
and
x:y:z is 1:1 to 10:0.1 to 5.

5. A manufacturing method of a resin composition, comprising:
manufacturing a copolymer, comprising:
dissolving at least a Lewis acid catalyst, an aromatic compound and an alicyclic compound in a solvent to form a first solution; and
using an alkali solution to perform a neutralization on the first solution, wherein the copolymer comprises an aromatic monomer and an alicyclic monomer, and a molecular weight of the copolymer is in a range of 2000 to 5000, and a proportion of the alicyclic monomer relative to the copolymer is 1% to 30%.

6. The manufacturing method of the resin composition according to claim 5, wherein the copolymer has a general chemical structural formula as follows: 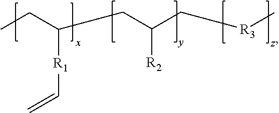
wherein
R₁ is derived from at least one of the following compounds: divinylbenzene, butadiene;
R₂ is derived from at least one of the following compounds: styrene, 4-vinylbiphenyl, 2-vinylnaphthalene;
R₃ is derived from at least one of the following compounds: acenaphthylene, cyclopentadiene, cyclobutadiene, norbornene, dicyclopentadiene; and
the x:y:z is 1:1 to 10:0.1 to 5.

7. The manufacturing method of the resin composition according to claim 5, wherein the Lewis acid catalyst comprises SnCl₄·H₂O or BF₃·Oet₃.

8. The manufacturing method of the resin composition according to claim 5, wherein the solvent comprises toluene or dimethyl formamide.

9. The manufacturing method of the resin composition according to claim 5, wherein the alkali solution comprises a NaHCO₃ aqueous solution.

10. The manufacturing method of the resin composition according to claim 5, wherein a reaction temperature of the neutralization is greater than or equal to 70° C.
